(19) United States
(12) Patent Application Publication
(10) Pub. No.: US 2024/0021498 A1
(43) Pub. Date: Jan. 18, 2024

(54) SEMICONDUCTOR DEVICE AND METHOD FOR MANUFACTURING SEMICONDUCTOR DEVICE

(71) Applicant: SONY SEMICONDUCTOR SOLUTIONS CORPORATION, Kanagawa (JP)

(72) Inventors: Takushi SHIGETOSHI, Kanagawa (JP); Naoto SASAKI, Kumamoto (JP); Kenichi SAITOU, Kumamoto (JP)

(73) Assignee: SONY SEMICONDUCTOR SOLUTIONS CORPORATION, Kanagawa (JP)

(21) Appl. No.: 18/255,385

(22) PCT Filed: Oct. 14, 2021
(86) PCT No.: PCT/JP2021/038052

§ 371 Date: Jun. 1, 2023

(30) Foreign Application Priority Data
Dec. 9, 2020 (JP) 2020-203843

(51) Int. Cl. H01L 23/48; H01L 23/00; H01L 23/528; H01L 21/768

(52) U.S. Cl. CPC H01L 23/481; H01L 23/564; H01L 23/528; H01L 21/76898

(57) ABSTRACT

A yield is improved in a semiconductor device in which a through electrode covered with an insulating film is formed. A semiconductor device includes a through electrode, an insulating film, and a wiring layer. In a semiconductor device including a through electrode, an insulating film, and a wiring layer, the through electrode penetrates the semiconductor substrate along a direction perpendicular to a predetermined front surface of the semiconductor substrate. Furthermore, the insulating film covers the through electrode. Moreover, the wiring layer includes a dummy gate disposed in a region between an outer periphery of the insulating film and an inner periphery of the insulating film on the front surface.

### TECHNICAL FIELD

The present technology relates to a semiconductor device. Specifically, the present technology relates to a semiconductor device in which a through electrode is formed, and a method for manufacturing the semiconductor device.

### BACKGROUND ART

Conventionally, research and development have been advanced on three-dimensional mounting technology using a through electrode in various semiconductor devices for the purpose of miniaturization and high integration. For example, a semiconductor device has been proposed in which a dummy pattern is formed outside a formation portion of a through electrode covered with an insulating film while avoiding the formation portion (see, for example, Patent Document 1).

### CITATION LIST

### Patent Document

### Patent Document 1: Japanese Patent Application Laid-Open No. 2010-21352

### SUMMARY OF THE INVENTION

### Problems to be Solved by the Invention

In the above-described conventional technique, the dummy pattern is not formed in the formation portion of the through electrode, thereby suppressing the notch generated in the side wall of the through electrode. However, if the dummy pattern is formed while avoiding the inside of the insulating film covering the through electrode, flatness of an interlayer insulating film is deteriorated due to excessive polishing during chemical mechanical polishing (CMP). Consequently, there is a possibility that the yield at the time of forming the wiring layer is deteriorated.

The present technology has been made in view of such a situation, and an object thereof is to improve the yield in a semiconductor device in which a through electrode covered with an insulating film is formed.

### Solutions to Problems

The present technology has been made to solve the above-described problems, and a first aspect thereof is a semiconductor device including a through electrode that penetrates a semiconductor substrate along a direction perpendicular to a predetermined front surface of the semiconductor substrate, an insulating film covering the through electrode, and a wiring layer that includes a dummy gate disposed in a region between an outer periphery of the insulating film and an inner periphery of the insulating film on the front surface, and a method for manufacturing the same. Thus, an effect of improving the yield is provided.

Furthermore, in the first aspect, the dummy gate may not be disposed inside the inner periphery. Thus, an effect of facilitating formation of the through electrode is provided.

Furthermore, in the first aspect, the dummy gate may be further disposed outside the outer periphery. Thus, an effect of improving the yield is provided.

Furthermore, in the first aspect, the semiconductor substrate may include an element isolation region formed under the wiring layer, and the dummy gate may be disposed on an upper portion of the element isolation region. Thus, an effect that the yield is improved by the dummy gate on the element isolation region is provided.

Furthermore, in the first aspect, an area ratio of the dummy gate may not be less than ten percent. Thus, an effect that an appropriate dummy pattern is formed is provided.

Furthermore, in the first aspect, a predetermined number of wirings may be formed in the wiring layer, and a pitch of the wirings inside the outer periphery may be substantially equal to a pitch of the wirings outside the outer periphery. Thus, an effect of facilitating the design of the device is provided.

Furthermore, in the first aspect, a gate electrode may be further disposed in the wiring layer, and a material of the dummy gate may be same as a material of the gate electrode. Thus, an effect of simplifying the manufacturing process is provided.

Furthermore, in the first aspect, the material of the dummy gate may be any of polycrystalline silicon, amorphous silicon, tungsten, titanium, tantalum, and aluminum. Thus, an effect of simplifying the manufacturing process is provided.

Furthermore, in the first aspect, a gate electrode may be further disposed in the wiring layer, and the material of the dummy gate may be different from a material of the gate electrode. Thus, an effect of preventing metal contamination is provided.

Furthermore, in the first aspect, a material of the dummy gate may be silicon nitride.

Thus, an effect of preventing metal contamination is provided.

Furthermore, in the first aspect, in the through electrode, a cross-sectional area of an upper end on a front surface side may be smaller than a cross-sectional area of a lower end on a back surface side with respect to the front surface, and the dummy gate may be disposed between the outer periphery of the insulating film covering the upper end of the front surface and the inner periphery of the insulating film covering the upper end. Thus, an effect that the effective aspect ratio of the through electrode is reduced is provided.

Furthermore, in the first aspect, in the through electrode, a cross-sectional area of an upper end on a front surface side may be larger than a cross-sectional area of a lower end on a back surface side with respect to the front surface, and the dummy gate may be disposed between the outer periphery of the insulating film covering the lower end of the front surface and the inner periphery of the insulating film covering the lower end. Thus, an effect of reducing a short circuit failure risk of the semiconductor substrate is provided.

Furthermore, in the first aspect, the semiconductor substrate may include an element isolation region formed over an entire surface of a region between the outer periphery of the insulating film and the inner periphery of the insulating film.

Furthermore, in the first aspect, the semiconductor substrate may include an element isolation region formed in a part of a region between the outer periphery of the insulating film and the inner periphery of the insulating film, and the dummy gate may be disposed on an upper side of the element isolation region. Thus, an effect of being able to cope with various design rules is provided.

Furthermore, in the first aspect, a gate electrode of a Fin field-effect transistor (Fin-FET) may be further disposed in the wiring layer. Thus, an effect that the yield is improved when the Fin-FET is used is provided.

### BRIEF DESCRIPTION OF DRAWINGS

FIG. 1 is an example of a cross-sectional view of a semiconductor device according to a first embodiment of the present technology.

FIG. 2 is an example of a plan view of a semiconductor substrate according to the first embodiment of the present technology.

FIG. 3 is an example of a plan view of a wiring layer according to the first embodiment of the present technology.

FIG. 4 is a diagram for explaining a manufacturing method up to formation of a metal dummy gate and a gate electrode according to the first embodiment of the present technology.

FIG. 5 is a diagram for explaining the manufacturing method up to formation of an insulating film according to the first embodiment of the present technology.

FIG. 6 is a diagram for explaining the manufacturing method up to formation of a through electrode according to the first embodiment of the present technology.

FIG. 7 is an example of a cross-sectional view of a semiconductor device in a comparative example.

FIG. 8 is an example of a cross-sectional view of a semiconductor device according to a second embodiment of the present technology.

FIG. 9 is a diagram for explaining a method for manufacturing the semiconductor device according to the second embodiment of the present technology.

FIG. 10 is an example of a cross-sectional view of a semiconductor device according to a third embodiment of the present technology.

FIG. 11 is an example of a cross-sectional view of a semiconductor device according to a fourth embodiment of the present technology.

FIG. 12 is an example of a plan view of a semiconductor substrate according to a fifth embodiment of the present technology.

FIG. 13 is an example of a plan view of a semiconductor substrate when element isolation regions are linearly formed according to the fifth embodiment of the present technology.

FIG. 14 is an example of a plan view of a semiconductor substrate when element isolation regions are concentrically formed according to the fifth embodiment of the present technology.

FIG. 15 is an example of a cross-sectional view of a semiconductor device according to a sixth embodiment of the present technology.

FIG. 16 is another example of a cross-sectional view of the semiconductor device according to the sixth embodiment of the present technology.

FIG. 17 is a block diagram depicting an example of schematic configuration of a vehicle control system.

FIG. 18 is a diagram of assistance in explaining an example of installation positions of an outside-vehicle information detecting section and an imaging section.

FIG. 19 is a diagram illustrating an example of a schematic configuration of an endoscopic surgery system.

FIG. 20 is a block diagram illustrating an example of functional configurations of a camera head and a CCU illustrated in FIG. 19.

### MODE FOR CARRYING OUT THE INVENTION

Hereinafter, modes for carrying out the present technology (hereinafter referred to as embodiments) will be described. The description will be given in the following order.

1. First embodiment (example in which dummy gate is disposed between outer periphery and inner periphery of insulating film)

2. Second embodiment (example in which dummy gate with material different from that of gate electrode is disposed between outer periphery and inner periphery of insulating film)

3. Third embodiment (example in which through electrode is tapered and dummy gate is disposed between outer periphery and inner periphery of insulating film)

4. Fourth embodiment (example in which through electrode is inversely tapered and dummy gate is disposed between outer periphery and inner periphery of insulating film)

5. Fifth embodiment (example in which dummy gate is disposed between outer periphery and inner periphery of insulating film, and element isolation region is partially formed)

6. Sixth embodiment (example in which dummy gate is disposed between outer periphery and inner periphery of insulating film and fin structure is employed for transistor)

7. Application example to mobile body

8. Application example to endoscopic surgery system

### 1. First Embodiment

### Configuration Example of Semiconductor Device

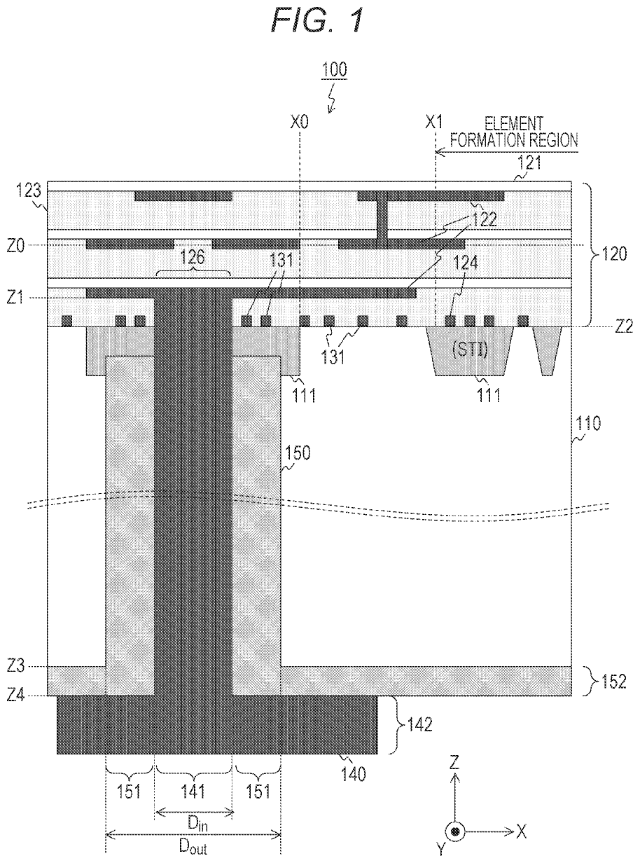

FIG. 1 is an example of a cross-sectional view of a semiconductor device 100 according to a first embodiment of the present technology. The semiconductor device 100 is a device provided with various elements and circuits such as a transistor and a signal processing circuit. As the semiconductor device 100, various circuits, elements, and devices such as a signal processing circuit, a memory, and an image sensor are assumed.

The semiconductor device 100 includes a semiconductor substrate 110, a wiring layer 120 formed on one of both surfaces of the semiconductor substrate 110, a conductor 140, and an insulator 150. Hereinafter, of both surfaces of the semiconductor substrate 110, the surface on which the wiring layer 120 is formed is referred to as a “front surface”, and a surface with respect to the front surface is referred to as a “back surface”. In addition, the front surface side is referred to as “upper side”, and the back surface side is referred to as “lower side”. Furthermore, a predetermined axis parallel to the front surface is referred to as an “X axis”, and an axis perpendicular to the front surface is referred to as a “Z axis”. An axis perpendicular to the X axis and the Z axis is referred to as a “Y axis”. The drawing is a cross-sectional view when viewed from the Y-axis direction.

The wiring layer 120 includes multiple layers, a predetermined number of wirings 122 are formed in each layer, and an interlayer insulating film 123 is formed between the layers. The upper surface of each layer is covered with a diffusion preventing film 121.

Furthermore, a predetermined number of metal dummy gates 131, a predetermined number of gate electrodes 124, and a pad 126 are further disposed in a lowermost layer of the wiring layer 120. Each of the gate electrodes 124 is arranged, for example, in an element formation region on the right side of the coordinate Xl.

Here, the gate electrodes 124 function as a transistor in the element formation region together with a source (not illustrated) and a drain (not illustrated). The transistor is not a FinFET (Field-Effect Transistor).

The metal dummy gate 131 is not used as a gate electrode of a transistor, and is formed for the purpose of preventing flatness of a surface of the insulating film from being impaired at the time of manufacturing the semiconductor device 100. A pattern including each of the metal dummy gates 131 is referred to as a “dummy pattern”. Note that the metal dummy gates 131 are an example of a dummy gate described in the claims.

Furthermore, in the semiconductor substrate 110, a predetermined number of element isolation regions 111 are formed under the wiring layer 120. For example, shallow trench isolation (STI) is used for the element isolation regions 111.

Furthermore, a part of the conductor 140 is filled in a through hole penetrating the semiconductor substrate 110 from the pad 126 to the back surface, and the rest forms a conductive film 142 on the back surface side. In the conductor 140, a portion in the through hole of the semiconductor substrate 110 is referred to as a through electrode 141. In the drawing, a portion from the coordinate Z1 to the coordinate Z4 of the conductor 140 corresponds to the through electrode 141, and a lower portion of Z4 corresponds to the conductive film 142. Furthermore, a black portion immediately above the coordinate Z1 corresponds to the pad 126.

Furthermore, a cross-sectional area of an upper end and a cross-sectional area of a lower end of the through electrode 141 are substantially the same. Here, “substantially the same” indicates that two values to be compared completely coincide with each other or have a difference within an allowable value.

Furthermore, a part of the insulator 150 covers the through electrode 141, and the rest forms an insulating film 152 covering the back surface of the semiconductor substrate 110. A portion of the insulator 150 covering the through electrode 141 is referred to as an insulating film 151. In the drawing, an upper portion of the insulator 150 in the coordinate Z3 corresponds to the insulating film 151, and a lower portion thereof corresponds to the insulating film 152.

The diameter of an outer periphery of the insulating film 151 is defined as an outer diameter Dₒᵤₜ, and the diameter of an inner periphery of the insulating film 151 is defined as an inner diameter Dᵢₙ. A part of the metal dummy gates 131 is disposed between the outer periphery and the inner periphery of the insulating film 151, and the rest is disposed outside the outer periphery.

Regarding the material of each part, the material of the gate electrodes 124 is also a metal material such as tungsten (W), titanium (Ti), tantalum (Ta), or aluminum (Al). Note that the material of the gate electrodes 124 may be a semiconductor material such as polycrystalline silicon or amorphous silicon. The material of each of the metal dummy gates 131 is, for example, a metal material similar to that of the gate electrodes 124. Note that, instead of the metal dummy gates 131, dummy gates including another material such as a semiconductor material can be disposed.

Note that the material of the dummy pattern between the outer periphery and the inner periphery of the insulating film 151 may be different from the dummy pattern outside the outer periphery. In this case, the material of the metal dummy gates 131 between the outer periphery and the inner periphery may be an insulating material that can serve as a CMP stopper, such as silicon nitride (SiN) or silicon carbide (SiC).

Furthermore, the material of the pad 126 is copper (Cu), titanium (Ti), tantalum (Ta), aluminum (Al), tungsten (W), nickel (Ni), ruthenium (Ru), cobalt (Co), or the like. As illustrated in the drawing, the pad 126 may be disposed in the lowermost layer in the wiring layer 120, or may be disposed in a layer above the lowermost layer. Furthermore, the pad 126 may be formed in a single layer in the wiring layer 120, or may be formed across a plurality of layers.

Furthermore, the interlayer insulating film 123 includes silicon dioxide (SiO₂), silicon nitride (SiN), silicon nitride oxide (SiON), silicon carbide (SiC), a low-k film, and the like.

In addition, as a material of the insulating film 151, an inorganic material such as SiO₂, SiN, SiON, or a low-k film, or an organic material having a polyimide, an acrylic, a silicone, or an epoxy group as a skeleton can be selected.

The through electrode 141 includes a material such as Cu, Ti, Ta, Al, W, Ni, Ru, or Co, and may be filled in the through hole or disposed so as to extend along a side surface of the through hole as illustrated in the drawing.

In addition, a wiring on the back surface side is formed by disposing the insulating film 152 and the patterned conductive film 142 on the back surface, and may be formed by the same material or may be formed separately at the same time as the through electrode 141.

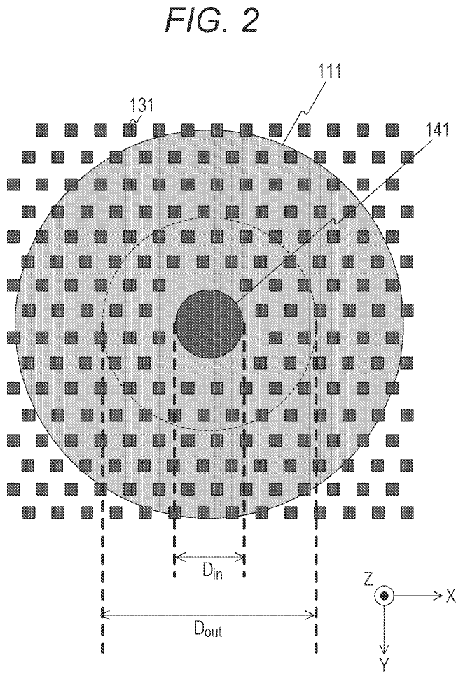

FIG. 2 is an example of a plan view of the semiconductor substrate 110 according to the first embodiment of the present technology. The drawing is a plan view of an X-Y plane (that is, a plane of the lowermost layer of the wiring layer 120) at a coordinate Z2 in FIG. 1 as viewed from above.

A dotted line surrounding the through electrode 141 in the drawing indicates the outer periphery of the insulating film 151 covering the through electrode 141. An outer periphery of the through electrode 141 corresponds to the inner periphery of the insulating film 151. The metal dummy gates 131 are disposed between the outer periphery and the inner periphery of the insulating film 151. Moreover, the metal dummy gates 131 are also disposed outside the outer periphery of the insulating film 151.

Furthermore, the element isolation region 111 (such as STI) is formed on the entire surface of the region between the outer periphery and the inner periphery of the insulating film 151. In the drawing, the element isolation region 111 is formed on the entire surface in a circle having a diameter larger than the outer periphery. Note that, as will be described later, the element isolation region 111 can be formed only in a part of the region between the outer periphery and the inner periphery of the insulating film 151 according to predetermined design rules. In addition, it is preferable to form the element isolation region 111 at a place where the dummy pattern is disposed at least inside the insulating film 151 (dotted line) so that the dummy pattern is not exposed when the through hole is opened in the semiconductor substrate 110.

In addition, the area ratio of the dummy pattern is determined according to a design rule of the area ratio of the wiring layer 120, and is preferably about 10 to 50%. Here, as a denominator of the area ratio, for example, a chip area of a semiconductor chip generated from the semiconductor substrate 110 is used.

The density and shape of the dummy pattern are not necessarily limited to those illustrated in the drawing, and can be freely selected according to the design rules.

Here, a comparative example is assumed in which the metal dummy gates 131 are not provided between the outer periphery and the inner periphery of the insulating film 151, and the metal dummy gates 131 are disposed outside the outer periphery. In this comparative example, flatness of the surface of the interlayer insulating film 123 may be impaired particularly on an upper side of the through hole by excessive polishing of the interlayer insulating film 123 at the time of CMP. For this reason, there is a possibility that the yield is reduced.

On the other hand, as illustrated in the drawing, in the semiconductor device 100 in which the metal dummy gates 131 are also disposed between the outer periphery and the inner periphery of the insulating film 151, it is possible to suppress excessive polishing during CMP and improve the flatness of the insulating film. Thus, it is possible to suppress a decrease in yield.

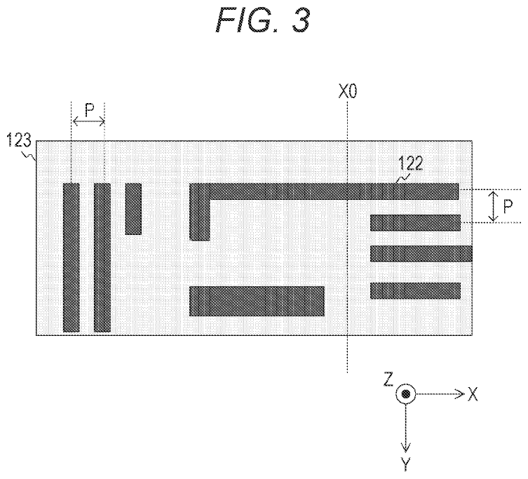

FIG. 3 is an example of a plan view of the wiring layer 120 according to the first embodiment of the present technology. The drawing is a plan view of an X-Y plane (that is, a plane of a layer above the lowermost layer in the wiring layer 120) at a coordinate Z0 in FIG. 1 as viewed from above.

The left side of the coordinate XO corresponds to a region where the through electrode 141 and the insulating film 151 are disposed. A plurality of wirings 122 is formed, and the pitch between the wirings is denoted by “P”. Here, the pitch indicates, for example, a distance between center lines of two adjacent wirings 122.

As described above, since the dummy pattern is arranged closer to the through electrode 141 than in the comparative example, flatness of the wiring layer around the through electrode 141 can be improved. Consequently, as illustrated in FIG. 3, even in a case of the wiring layer above the through electrode (such as on the left side of the coordinate XO), it is possible to form the wiring at the same minimum pitch as the other regions.

Furthermore, the distance between the outer diameter and the inner diameter of the insulating film 151 depends on the thickness of the interlayer insulating film 123, and thus the present invention is more effective in a structure in which the interlayer insulating film 123 is thicker. For example, it is suitable that the inner diameter of the insulating film 151 is 10 to 150 micrometers (μm), the outer diameter is 13 to 200 micrometers (μm), and the outer diameter is 1.3 times or more the inner diameter.

### Method for Manufacturing Semiconductor Device

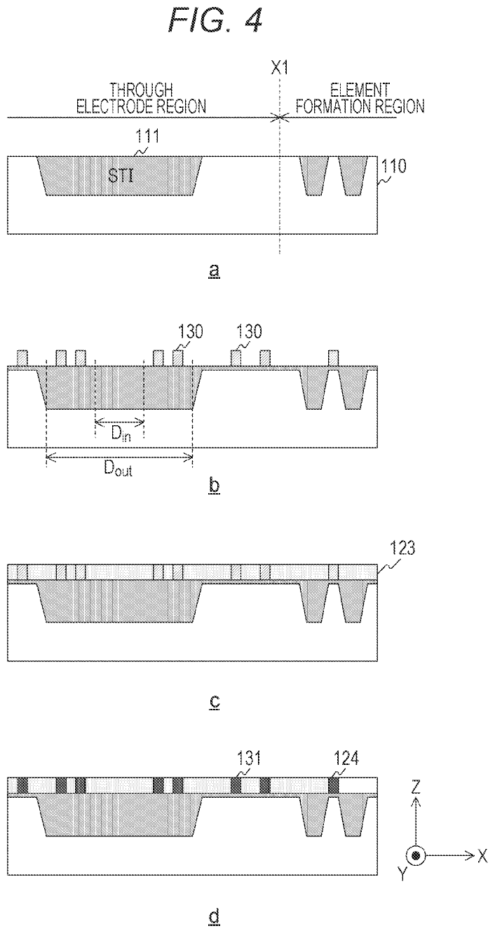

A method for manufacturing the semiconductor device 100 will be described with reference to FIGS. 4 to 6.

FIG. 4 is a diagram for explaining a manufacturing method up to formation of the metal dummy gates and the gate electrodes according to the first embodiment of the present technology. First, as illustrated in a of the drawing, a manufacturing system for the semiconductor device 100 forms the element isolation region 111 by STI. In a subsequent process, the STI is formed on the entire surface in a region inside the outer periphery of the insulating film 151.

Next, as exemplified in b of the drawing, silicon dummy gates 130 are formed. Here, an example of a gate last process generally used in a metal gate process is described. The manufacturing system forms a gate insulating film on the front surface of the semiconductor substrate 110, and then forms the silicon dummy gates 130 including polycrystalline silicon or amorphous silicon. At this time, the silicon dummy gates 130 are also disposed at positions between the outer diameter Dₒᵤₜ and the inner diameter Dᵢₙ of the insulating film 151. The dummy pattern is not disposed in a region inside the inner diameter Dᵢₙ because the dummy pattern hinders formation of the through electrode 141.

Next, as illustrated in c of the drawing, the manufacturing system planarizes the interlayer insulating film 123 by CMP using the silicon dummy gates 130 as a stopper after forming the interlayer insulating film 123. At this time, in a case where there is no silicon dummy gate 130 in a wide range, excessive polishing of the interlayer insulating film 123 occurs due to dishing, the flatness of the surface is impaired, and this causes a decrease in yield. However, since the silicon dummy gates 130 are also disposed at a position between the outer diameter Dₒᵤₜ and the inner diameter Dᵢₙ of the insulating film 151, a decrease in flatness inside the inner diameter Dᵢₙ is suppressed.

Next, as illustrated in d in the drawing, the silicon dummy gates 130 are removed by dry etching or wet etching to form a gate insulating film and a gate electrode, and then an excessive film is removed by CMP. Thus, the metal dummy gates 131 and the gate electrodes 124 are separately formed. Note that the silicon dummy gates 130 are an example of a first dummy gate described in the claims, and the metal dummy gates 131 are an example of a second dummy gate described in the claims.

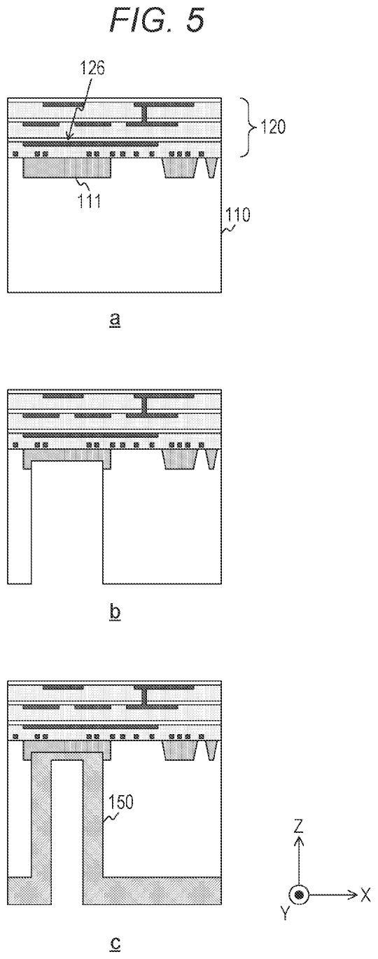

FIG. 5 is a diagram for explaining a manufacturing method up to formation of the insulating film according to the first embodiment of the present technology. After FIG. 4, the manufacturing system forms the multilayer wiring layer 120 using an existing technology as illustrated in a of FIG. 5. The pad 126 is formed in a region of the lowermost layer of the wiring layer 120 where the through electrode is disposed.

Next, as illustrated in b of the drawing, the manufacturing system forms the through hole in the semiconductor substrate 110 by dry etching. At this time, the element isolation region 111 (STI) serves as a stopper for dry etching. Since the dummy pattern is not exposed by using the STI as a stopper, it is possible to avoid a decrease in reliability of the semiconductor device due to metal scattering of the dummy pattern and a short circuit failure via the dummy pattern.

Next, as illustrated in c of the drawing, the manufacturing system forms the insulator 150 that separates the through electrode and the semiconductor substrate 110 by plasma-enhanced (PE)-chemical vapor deposition (CVD), atomic layer deposition (ALD), or application of resin. Thus, the insulating film is formed on the side surface and the back surface of the through hole. At this time, the insulating film is formed so that the film formation amount on the back surface side of the semiconductor substrate 110 is larger than that of the bottom portion of the through hole.

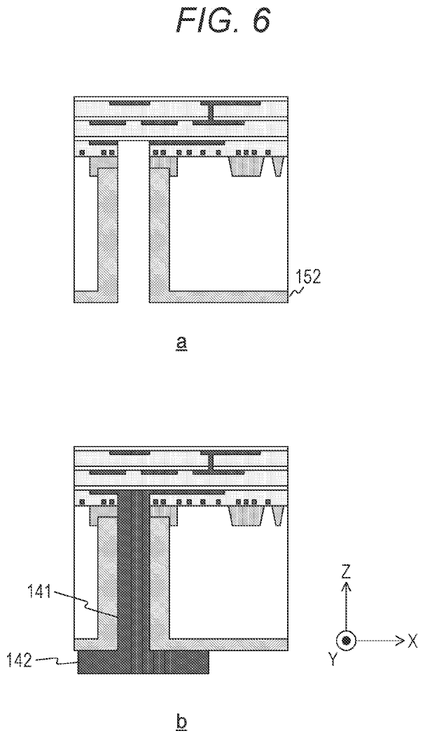

FIG. 6 is a diagram for explaining the manufacturing method up to formation of the through electrode 141 according to the first embodiment of the present technology.

After FIG. 5, the manufacturing system removes the insulating film at the bottom portion of the through hole by dry etching as illustrated in a of FIG. 6. Since there is a difference in film formation amount between the bottom portion and the back surface side as described above, the insulating film remaining on the back surface side becomes the insulating film 152 between the wiring on the back surface side and the semiconductor substrate 110.

Next, as illustrated in b of FIG. 6, the manufacturing system forms a conductive film using a physical vapor deposition (PE-PVD) method, a PE-CVD method, electroplating, electroless plating, or the like to form the through electrode 141. Moreover, the manufacturing system forms the back surface wiring by patterning the conductive film 142 on the back surface.

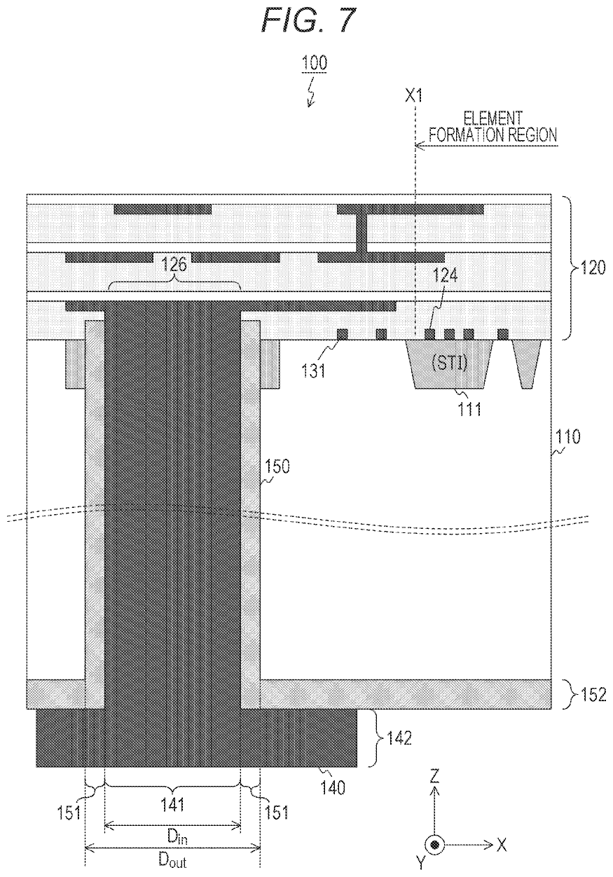

FIG. 7 is an example of a cross-sectional view of a semiconductor device in a comparative example. The through electrode 141 has a structure embedded in the through hole of the semiconductor substrate 110 via the insulating film 151, and connects the pad 126 formed in the wiring layer 120 of the semiconductor device 100 and the wiring or bump on the back surface of the semiconductor substrate 110.

Now, when the through electrode 141 is formed from the back surface side by what is called a via last process, it is necessary to consider the structure on the front surface side so as not to hinder through hole processing and so as to make the processing amount uniform. Therefore, it is desirable that the pad 126 is formed by a single layer of the lowermost layer in the wiring layer 120, the gate electrode is excluded, and the element isolation region 111 is excluded or arranged on the entire surface.

On the other hand, the transistor and wiring of the semiconductor device 100 are manufactured in accordance with design restrictions (design rules) provided for each layer, and in a case where the manufacturing is deviated from the design restrictions, process variation increases and the yield deteriorates. Since the size of the through electrode 141 is 10 times or more the size of the transistor and the wiring of the semiconductor device, it is difficult to arrange the pad 126, the gate electrodes 124, and the element isolation region 111 ideally for forming the through electrode 141.

By the way, CMP using a dummy gate as a stopper is performed in a gate last method which is a mainstream in recent advanced process. When all the dummy gates inside the insulating film 151 are removed as in the comparative example, the flatness of the interlayer insulating film 123 is deteriorated due to dishing during the CMP, so that the yield at the time of forming the wiring layer 120 is deteriorated. On the other hand, if a dummy gate is disposed inside the outer periphery of the through electrode 141, it becomes an obstacle at the time of processing the through electrode 141, which causes a decrease in reliability and an open defect.

On the other hand, in the semiconductor device 100 of FIG. 1, since the metal dummy gates 131 are also disposed inside the outer periphery and the inner periphery of the insulating film 151, it is possible to improve the yield when the wiring layer 120 is formed.

As described above, according to the first embodiment of the present technology, since the metal dummy gates 131 are also disposed inside the outer periphery and the inner periphery of the insulating film 151, it is possible to prevent the flatness of the interlayer insulating film 123 from deteriorating due to dishing during the CMP. This, it is possible to improve the yield when the wiring layer 120 is formed.

### 2. Second Embodiment

In the first embodiment described above, the metal dummy gates 131 are disposed, but in this configuration, in a case where a defect that the dummy pattern is exposed occurs due to process variation during processing of the through hole, metal contamination of the device may occur. The semiconductor device 100 of the second embodiment is different from that of the first embodiment in that a material of a dummy pattern is changed.

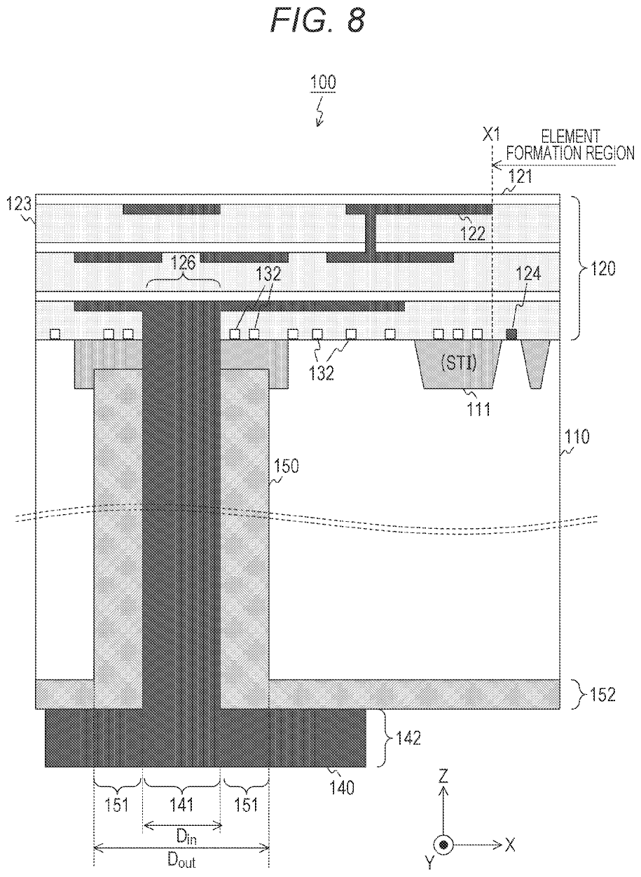

FIG. 8 is an example of a cross-sectional view of the semiconductor device 100 according to a second embodiment of the present technology. The semiconductor device 100 of the second embodiment is different from that of the first embodiment in that a SiN dummy gate 132 is disposed instead of the metal dummy gates 131.

Note that the material of the dummy gate is not limited to an insulating material such as SiN as long as the material is different from the metal gate electrodes 124. For example, a semiconductor material such as polycrystalline silicon or amorphous silicon can be used as the material of the dummy gate.

By using a material different from that of the gate electrodes 124 for the dummy pattern, metal contamination of the device can be prevented even if a defect occurs in which the dummy pattern is exposed due to process variation during processing of the through hole. In addition, in a case where the material of the dummy pattern is an insulating material, the short circuit failure risk via the dummy pattern can be further reduced.

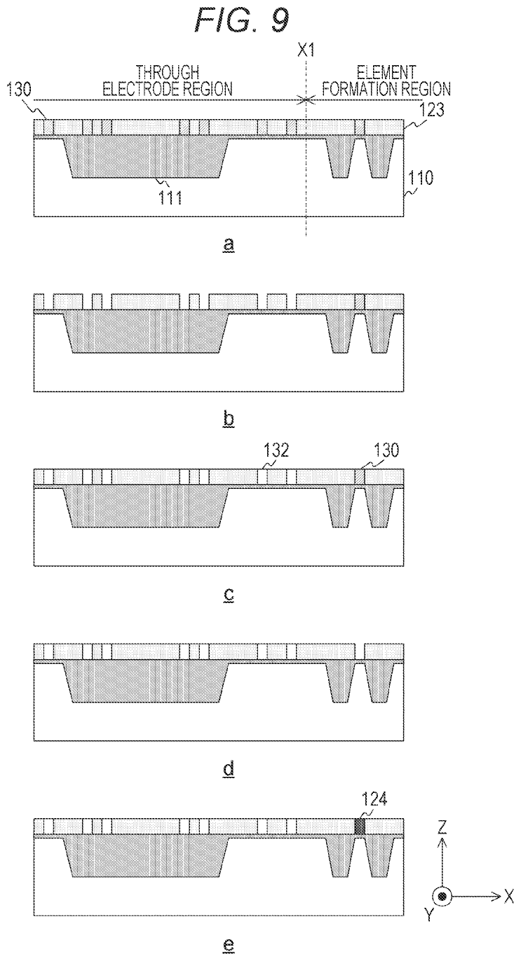

FIG. 9 is a diagram for explaining the method for manufacturing the semiconductor device 100 according to the second embodiment of the present technology. a in the drawing corresponds to c of FIG. 4 in the first embodiment, and is a state in which the silicon dummy gates 130 are formed. The manufacturing method of the second embodiment up to this point is similar to that of the first embodiment.

Then, as illustrated in b of the drawing, the manufacturing system performs dry etching in a state where the element formation region is covered by lithography, and removes the silicon dummy gates 130 in a through electrode region on the left side of the element formation region.

Next, as illustrated in c in the drawing, the manufacturing system forms a film of SiN by LP-CVD, PE-CVD, or an ALD method, and removes the excess by CMP or dry etching to form the SiN dummy gate 132.

Next, as illustrated in d in the drawing, the manufacturing system removes the silicon dummy gates 130 in the element formation region by dry etching or wet etching.

Next, as illustrated in e in the drawing, the metal gate material is deposited, and then the excess is removed by CMP to form the gate electrodes 124. By the manufacturing method illustrated in the drawing, a dummy pattern having a structure different from that of the gate electrodes 124 can be formed in the through electrode region.

As described above, according to the second embodiment of the present technology, since the dummy gate with a material different from that of the gate electrodes 124 is formed, it is possible to prevent metal contamination of the device in a case where a defect occurs in which the dummy pattern is exposed during processing of the through hole.

### 3. Third Embodiment

In the first embodiment described above, the cross-sectional area of the upper end of the through electrode 141 is substantially the same as the cross-sectional area of the lower end, but with this configuration, it is difficult to reduce the effective aspect ratio of the through electrode 141. The semiconductor device 100 of a third embodiment is different from that of the first embodiment in that a through electrode 141 is tapered (in other words, forward tapered) when viewed from the back surface side.

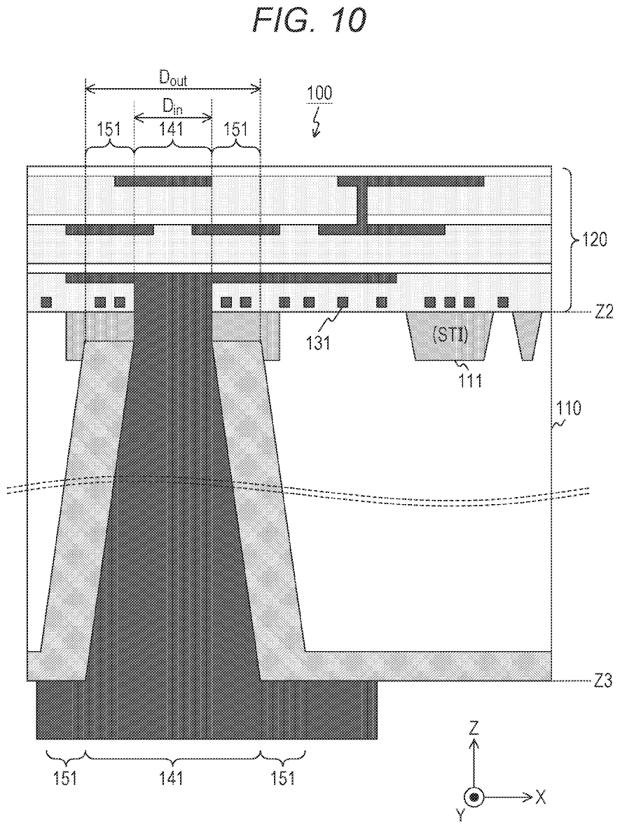

FIG. 10 is an example of a cross-sectional view of the semiconductor device 100 according to a third embodiment of the present technology. The through electrode 141 of the third embodiment is different from that of the first embodiment in that the cross-sectional area of the upper end is smaller than the cross-sectional area of the lower end. For example, the coordinate Z2 in the drawing corresponds to the position of the upper end, and the coordinate Z3 corresponds to the position of the lower end. That is, the through electrode 141 is forward tapered when viewed from the back surface side.

In a case where the through electrode 141 is forward tapered, the positions of the inner periphery and the outer periphery of the insulating film 151 are different between the upper end and the lower end. In this case, the metal dummy gates 131 are disposed between the inner periphery and the outer periphery of the insulating film 151 covering the upper end. Thus, effects similar to those of the first embodiment can be obtained.

Moreover, by forming the through electrode 141 is forward tapered, it is possible to increase an opening width on the back surface side while suppressing the use area on the front surface side of the semiconductor substrate 110. Consequently, the effective aspect ratio of the through electrode 141 can be reduced, and thus dry etching and formation of the insulating film and the conductive film are facilitated.

Note that the second embodiment can also be applied to the third embodiment.

As described above, according to the third embodiment of the present technology, since the through electrode 141 is forward tapered, it is possible to reduce the effective aspect ratio of the through electrode 141 by increasing the opening width on the back surface side while suppressing the use area on the front surface side of the semiconductor substrate 110.

### 4. Fourth Embodiment

In the first embodiment described above, the cross-sectional area of the upper end of the through electrode 141 is substantially the same as the cross-sectional area of the lower end, but with this configuration, it is difficult to reduce the short circuit failure risk between the through electrode 141 and the semiconductor substrate 110 via the side surface in the manufacturing process. The semiconductor device 100 of a fourth embodiment is different from that of the first embodiment in that the through electrode 141 is inversely tapered.

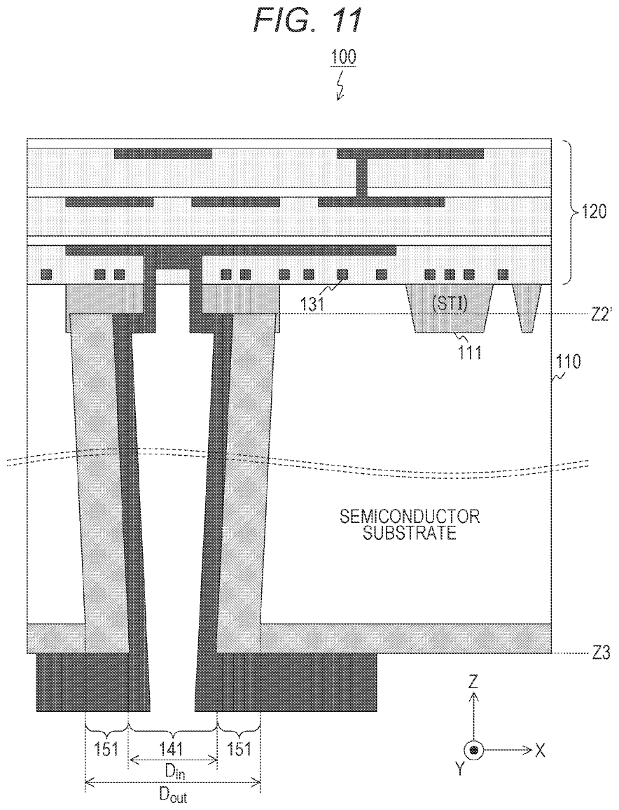

FIG. 11 is an example of a cross-sectional view of the semiconductor device 100 according to the fourth embodiment of the present technology. The through electrode 141 of the fourth embodiment is different from that of the first embodiment in that the cross-sectional area of the upper end is larger than the cross-sectional area of the lower end. For example, the coordinate Z2′ in the drawing corresponds to the position of the upper end, and the coordinate Z3 corresponds to the position of the lower end. That is, the through electrode 141 is inversely tapered when viewed from the back surface side.

In a case where the through electrode 141 is inversely tapered, the positions of the inner periphery and the outer periphery of the insulating film 151 are different between the upper end and the lower end. In this case, the metal dummy gates 131 are disposed between the inner periphery and the outer periphery of the insulating film 151 covering the lower end. Thus, effects similar to those of the first embodiment can be obtained.

Moreover, by forming the through electrode 141 in an inversely tapered shape, when the insulating film at the bottom portion of the through electrode 141 is removed by dry etching, the insulating film on the side surface of the through electrode 141 can be processed without being etched. Consequently, the short circuit failure risk between the through electrode 141 and the semiconductor substrate 110 through the side surface can be reduced.

Note that the second embodiment can also be applied to the fourth embodiment.

As described above, according to the fourth embodiment of the present technology, since the through electrode 141 is inversely tapered, it is possible to reduce the short circuit failure risk between the through electrode 141 and the semiconductor substrate 110 via the side surface when removing the insulating film at the bottom portion of the through electrode 141.

### 5. Fifth Embodiment

In the first embodiment described above, the element isolation regions 111 are formed on the entire surface of the region between the outer periphery and the inner periphery of the insulating film 151, but may also be formed in a part of the region. The semiconductor device 100 of a fifth embodiment is different from that of the first embodiment in that the element isolation regions 111 are formed in a part of the region between the outer periphery and the inner periphery of the insulating film 151.

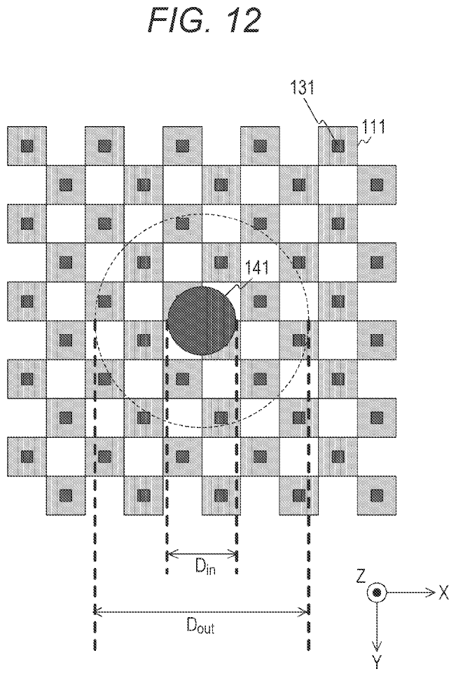

FIG. 12 is an example of a plan view of the semiconductor substrate 110 according to the fifth embodiment of the present technology. As illustrated in the drawing, in the fifth embodiment, the element isolation regions 111 (STIs) are formed in a part between the outer periphery (dotted line) of the insulating film 151 and the outer periphery of the through electrode 141 (that is, the inner periphery of the insulating film 151). The STIs and regions not corresponding to the STIs are mixed, and for example, when the STIs are black and the regions not corresponding to the STIs are white, the STIs are arranged in a checker flag shape. The dummy pattern is arranged on each STI.

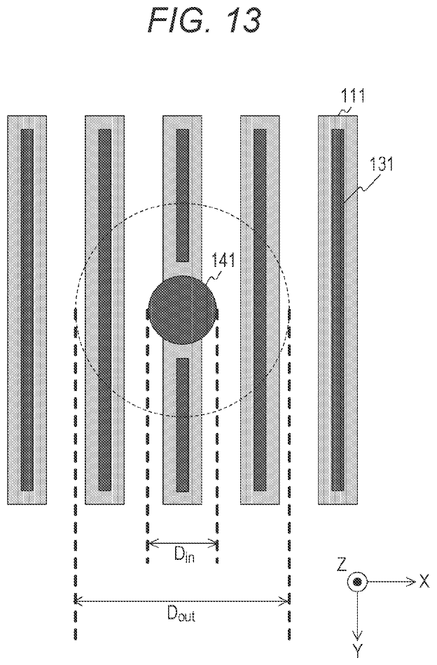

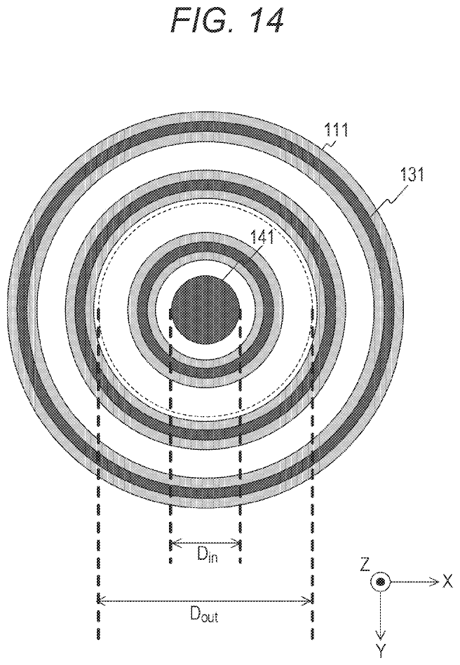

The arrangement of the STIs is not necessarily limited to that described in the drawing, and can be freely selected according to the design rules. For example, in a case where a self-aligned patterning method is used in the element isolation process or the gate electrode formation process, a linear shape may be preferred to a rectangular shape in terms of manufacturing. In this case, for example, as illustrated in FIG. 13, the STIs can be formed along the horizontal direction or the vertical direction. Alternatively, as illustrated in FIG. 14, the STIs can be formed concentrically. By forming the STIs in this manner, a uniform and symmetric dummy pattern can be formed.

Note that each of the second, third, and fourth embodiments can also be applied to the fifth embodiment.

As described above, according to the fifth embodiment of the present technology, since the element isolation regions 111 are formed in a part of the region between the outer periphery and the inner periphery of the insulating film 151, it is possible to cope with various design rules.

### 6. Sixth Embodiment

In the first embodiment described above, transistors other than FinFETs are arranged, but FinFETs can also be used. The semiconductor device 100 of a sixth embodiment is different from that of the first embodiment in that a FinFET is used.

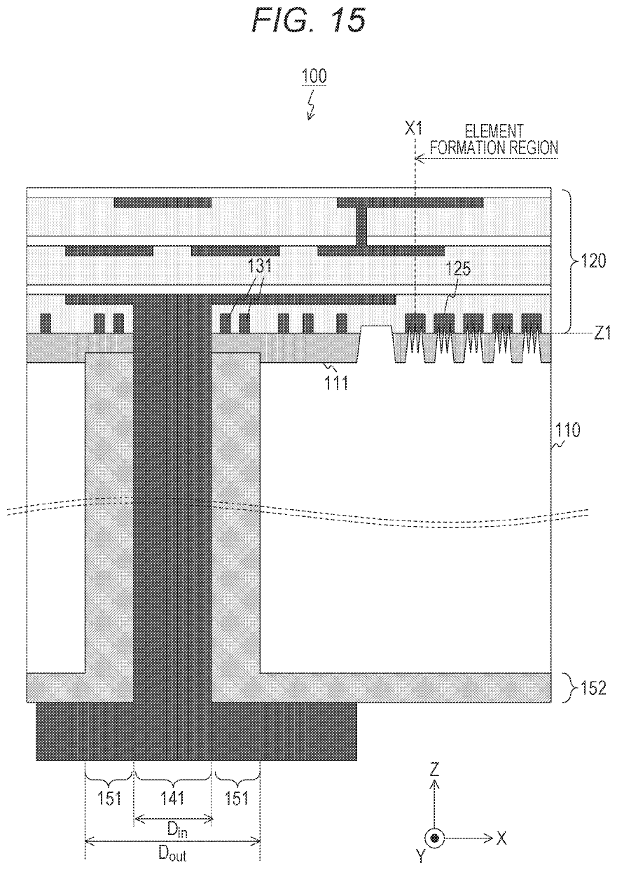

FIG. 15 is an example of a cross-sectional view of the semiconductor device 100 according to the sixth embodiment of the present technology. The semiconductor device 100 of the sixth embodiment is different from that of the first embodiment in that gate electrodes 125 are disposed instead of the gate electrodes 124 having a normal shape. The gate electrode 125, the source, and the drain constitute a FinFET. By employing the FinFET, a faster switching time and a high current density can be achieved.

In a case where FinFETs are disposed, as illustrated in the drawing, the element isolation region 111 is formed on the entire surface of the region between the inner periphery and the outer periphery of the insulating film 151.

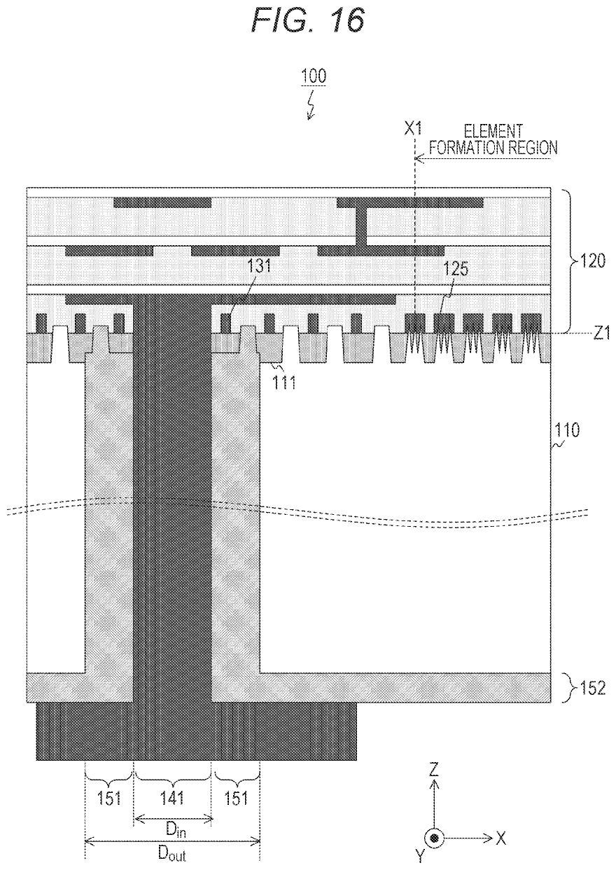

Note that, as illustrated in FIG. 16, the element isolation region 111 (STI) can also be formed in a part of the region between the inner periphery and the outer periphery of the insulating film 151. That is, the fifth embodiment can be further applied. In this case, the dummy pattern is preferably arranged on the STI at least inside the outer diameter of the insulating film 151.

Note that each of the second, third, and fourth embodiments can also be applied to the sixth embodiment.

As described above, according to the sixth embodiment of the present technology, since the FinFET is used, an earlier switching time and a high current density can be achieved.

### 7. Application Example to Mobile Body

The technology according to the present disclosure (the present technology) can be applied to various products. For example, the technology according to the present disclosure may be achieved as a device mounted on any type of mobile body such as an automobile, an electric vehicle, a hybrid electric vehicle, a motorcycle, a bicycle, a personal mobility, an airplane, a drone, a boat, a robot, and the like.

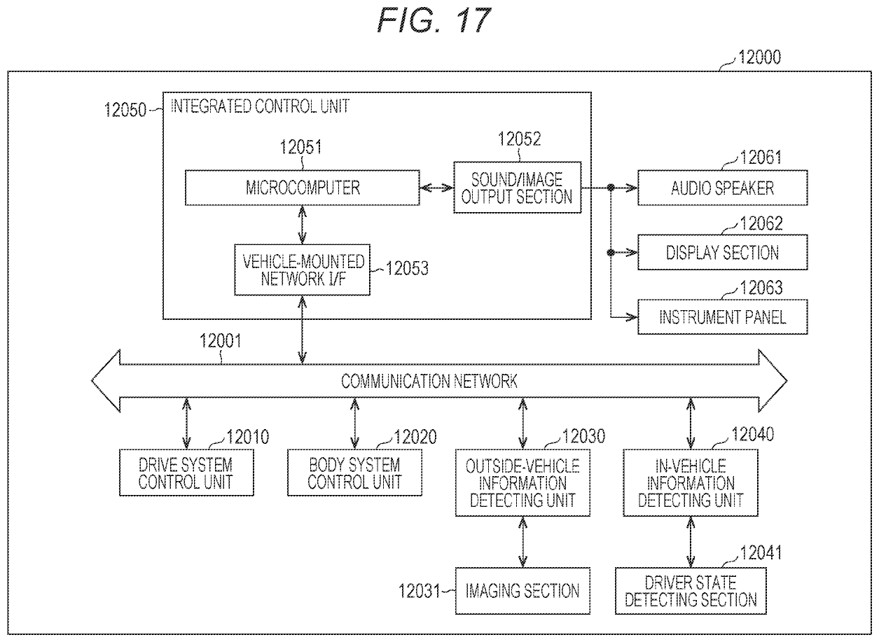

FIG. 17 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 17, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 17, an audio speaker 12061, a display section 12062, and an instrument panel 12063 are illustrated as the output device. The display section 12062 may, for example, include at least one of an on-board display and a head-up display.

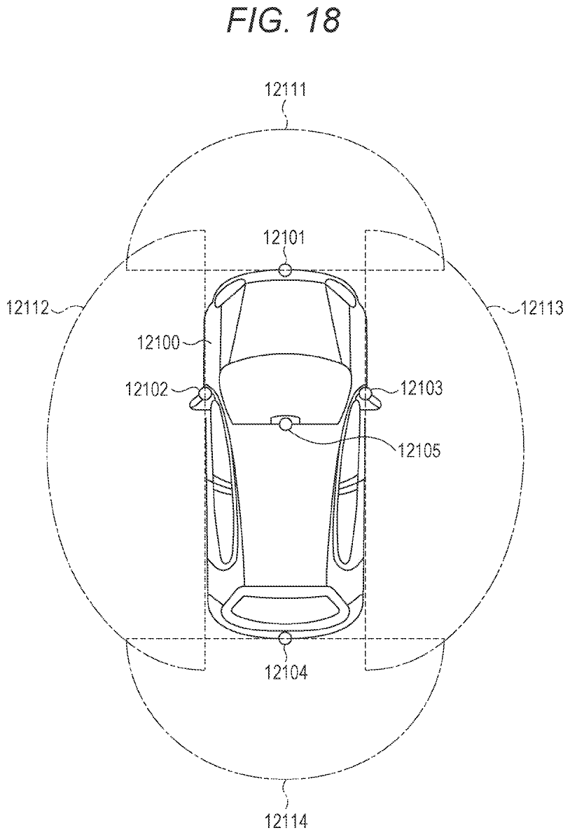

FIG. 18 is a diagram depicting an example of the installation position of the imaging section 12031.

In FIG. 18, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 18 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The example of the vehicle control system to which the technology according to the present disclosure is applicable has been described above. The technology according to the present disclosure can be applied to, for example, the imaging section 12031 among the above-described configurations. Specifically, the semiconductor device 100 in FIG. 1 can be applied to the imaging section 12031. By applying the technology according to the present disclosure to the imaging section 12031, it is possible to improve the yield of the imaging section 12031.

### 8. Application Example to Endoscopic Surgery System

The technology according to the present disclosure can be applied to various products. For example, the technology according to the present disclosure may be applied to an endoscopic surgery system.

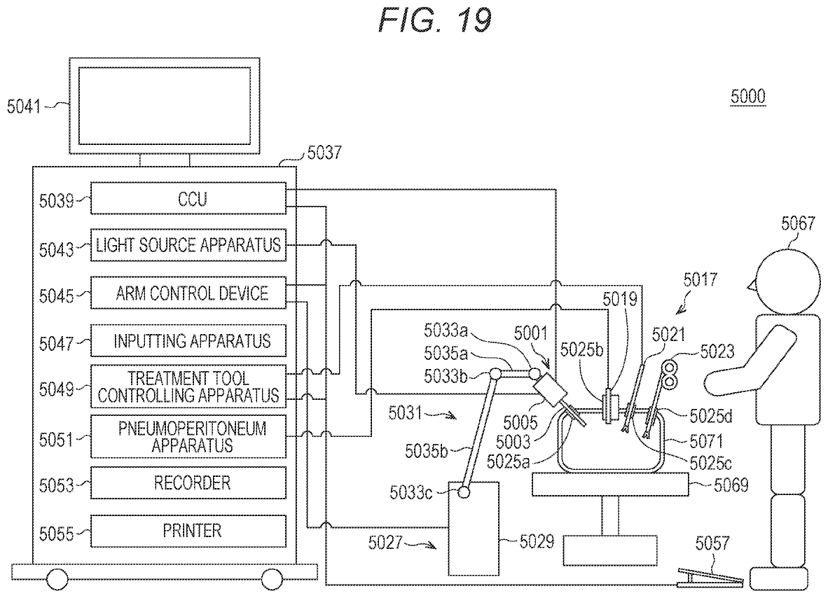

FIG. 19 is a diagram illustrating an example of a schematic configuration of an endoscopic surgery system 5000 to which the technology according to the present disclosure is applicable. In FIG. 19, a state is illustrated in which a surgeon (medical doctor) 5067 is using an endoscopic surgery system 5000 to perform surgery for a patient 5071 on a patient bed 5069. As illustrated, the endoscopic surgery system 5000 includes an endoscope 5001, other surgical tools 5017, a support arm device 5027 that supports the endoscope 5001, and a cart 5037 on which various devices for endoscopic surgery are mounted.

In endoscopic surgery, instead of cutting the abdominal wall to open the abdomen, a plurality of tubular opening devices called trocars 5025a to 5025d is introduced through the abdominal wall. Then, a lens barrel 5003 of the endoscope 5001 and other surgical tools 5017 are inserted into the body cavity of the patient 5071 through the trocars 5025a to 5025d. In the illustrated example, a pneumoperitoneum tube 5019, an energy treatment device 5021, and forceps 5023 are inserted into the body cavity of the patient 5071 as the other surgical tools 5017. Furthermore, the energy treatment device 5021 is a treatment tool that performs incision and peeling of tissue, sealing of blood vessels, or the like by high-frequency current or ultrasonic vibration. However, the illustrated surgical tools 5017 are merely examples, and various surgical tools generally used in endoscopic surgery, such as tweezers and a retractor, may be used as the surgical tools 5017.

An image of the surgical site in the body cavity of the patient 5071 taken by the endoscope 5001 is displayed on a display device 5041. The surgeon 5067 performs a procedure such as excising the affected site using the energy treatment device 5021 and the forceps 5023, for example, while viewing in real-time the image of the surgical site displayed on the display device 5041. Note that although illustration is omitted, the pneumoperitoneum tube 5019, the energy treatment device 5021, and the forceps 5023 are supported by the surgeon 5067 or an assistant during surgery or the like.

### Support Arm Device

The support arm device 5027 includes an arm 5031 extending from a base unit 5029. In the illustrated example, the arm 5031 includes joints 5033a, 5033b, and 5033c and links 5035a and 5035b, and is driven by control from an arm control device 5045. The arm 5031 supports the endoscope 5001, and the position and posture of the endoscope 5001 are controlled. Thus, stable fixation of the position of the endoscope 5001 can be achieved.

### Endoscope

The endoscope 5001 includes a lens barrel 5003 having a region of a predetermined length from a distal end thereof to be inserted into a body cavity of the patient 5071, and a camera head 5005 connected to a proximal end of the lens barrel 5003. In the illustrated example, the endoscope 5001 configured as what is called a rigid endoscope having a rigid lens barrel 5003 is illustrated, but the endoscope 5001 may be configured as what is called a flexible mirror having a flexible lens barrel 5003.

An opening in which an objective lens is fitted is provided in the distal end of the lens barrel 5003. A light source apparatus 5043 is connected to the endoscope 5001, and light generated by the light source apparatus 5043 is guided to the distal end of the lens barrel by a light guide extending inside the lens barrel 5003, and is emitted toward an observation target in the body cavity of the patient 5071 via the objective lens. Note that the endoscope 5001 may be a forward-viewing endoscope, an oblique-viewing endoscope, or a side-viewing endoscope.

An optical system and an imaging element are provided inside the camera head 5005, and reflected light (observation light) from the observation target is focused on the imaging element by the optical system. The observation light is photo-electrically converted by the imaging element to generate an electric signal corresponding to the observation light, namely, an image signal corresponding to an observation image. The image signal is transmitted to a camera control unit (CCU) 5039 as RAW data. Note that the camera head 5005 is equipped with a function of adjusting magnification and focal length by appropriately driving the optical system.

Note that the camera head 5005 may be provided with a plurality of imaging elements in order to support stereoscopic viewing (3D display) or the like, for example. In this case, a plurality of relay optical systems is provided inside the lens barrel 5003 in order to guide the observation light to each of the plurality of imaging elements.

### Various Devices Mounted on Cart

The CCU 5039 includes a central processing unit (CPU), a graphics processing unit (GPU) or the like and integrally controls operation of the endoscope 5001 and a display device 5041. Specifically, the CCU 5039 subjects an image signal received from the camera head 5005 to various image processing such as development processing (demosaic processing) for example for displaying an image based on the image signal. The CCU 5039 provides the display device 5041 with the image signal subjected to the image processing. Furthermore, the CCU 5039 transmits a control signal to the camera head 5005 and controls driving thereof. The control signal may include information regarding imaging conditions such as magnification and focal length.

By control from the CCU 5039, the display device 5041 displays an image based on the image signal subjected to the image processing by the CCU 5039. In a case where the endoscope 5001 is compatible with, for example, high-resolution imaging such as 4K (3840 horizontal pixels×2160 vertical pixels) or 8K (7680 horizontal pixels×4320 vertical pixels), and/or 3D display, a display device capable of high-resolution display and/or capable of 3D display in a respectively compatible manner can be used as the display device 5041. In a case where it is compatible with high-resolution imaging such as 4K or 8K, more immersive feeling can be obtained by using a display having a size of 55 inches or more as the display device 5041. Furthermore, a plurality of display devices 5041 having different resolutions and sizes may be provided depending on the application.

The light source apparatus 5043 includes, for example, a light source such as a light emitting diode (LED), and supplies the endoscope 5001 with irradiation light at the time of imaging the surgical site.

The arm control device 5045 includes a processor such as a CPU, for example, and operates according to a predetermined program so as to control driving of the arm 5031 of the support arm device 5027 according to a predetermined control method.

An inputting apparatus 5047 is an input interface for the endoscopic surgery system 5000. The user can input various information and instructions to the endoscopic surgery system 5000 via the inputting apparatus 5047. For example, the user inputs various information regarding the surgery, such as physical information of the patient and information regarding a surgical procedure, through the inputting apparatus 5047. Furthermore, for example, the user inputs, via the inputting apparatus 5047, an instruction to drive the arm 5031, an instruction to change imaging conditions (type of irradiation light, magnification, focal length, and so on) by the endoscope 5001, an instruction to drive the energy treatment device 5021, or the like.

The type of the inputting apparatus 5047 is not limited, and the inputting apparatus 5047 may be various known inputting apparatuses. As the inputting apparatus 5047, for example, a mouse, a keyboard, a touch panel, a switch, a foot switch 5057, and/or a lever or the like can be applied. In a case where a touch panel is used as the inputting apparatus 5047, the touch panel may be provided on the display surface of the display device 5041.

Alternatively, for example, the inputting apparatus 5047 is a device worn by the user, such as a glasses-type wearable device or a head mounted display (HMD), and various inputs are performed according to a gesture or line of sight of the user detected by these devices. Furthermore, the inputting apparatus 5047 includes a camera capable of detecting a movement of the user, and various inputs are performed according to a gesture or line of sight of the user detected from the image captured by the camera. Moreover, the inputting apparatus 5047 includes a microphone capable of collecting voice of the user, and various inputs are performed by voice through the microphone. Thus, by the inputting apparatus 5047 configured to be capable of inputting various kinds of information in a contactless manner, particularly a user (for example, a surgeon 5067) who belongs to a clean area can operate devices belonging to an unclean area in a contactless manner. Furthermore, the user can operate the devices without taking his or her hand off the surgical tool that he or she is holding, and thus the convenience for the user is improved.

A treatment tool controlling apparatus 5049 controls driving of the energy treatment device 5021 for cautery or incision of a tissue, sealing of a blood vessel or the like. A pneumoperitoneum apparatus 5051 feeds gas into a body cavity of the patient 5071 through the pneumoperitoneum tube 5019 to inflate the body cavity in order to secure the field of view of the endoscope 5001 and secure the working space for the surgeon. A recorder 5053 is a device capable of recording various information regarding surgery. A printer 5055 is a device capable of printing various information regarding surgery in various formats such as text, image, or graph.

Hereinafter, a particularly characteristic configuration of the endoscopic surgery system 5000 will be described in more detail.

### Support Arm Device

The support arm device 5027 includes a base unit 5029, which is a base, and an arm 5031 extending from the base unit 5029. In the illustrated example, the arm 5031 includes a plurality of joints 5033a, 5033b, and 5033c and a plurality of links 5035a and 5035b connected by the joint 5033b, but in FIG. 19, for simplicity, the configuration of the arm 5031 is illustrated in a simplified manner. In practice, the shapes, numbers, and arrangement of the joints 5033a to 5033c and the links 5035a and 5035b, and directions of rotation axes of the joints 5033a to 5033c and the like are appropriately set so that the arm 5031 has a desired degree of freedom. For example, preferably, the arm 5031 may have six or more degrees of freedom. Thus, the endoscope 5001 can be freely moved within a movable range of the arm 5031, and hence it is possible to insert the lens barrel 5003 of the endoscope 5001 into the body cavity of the patient 5071 from a desired direction.

The joints 5033a to 5033c are provided with actuators, and the joints 5033a to 5033c may be rotatable about a predetermined rotation axis by driving the actuators. By controlling driving of the actuators by the arm control device 5045, the rotation angles of the respective joints 5033a to 5033c are controlled and driving of the arm 5031 is controlled. Thus, control of the position and posture of the endoscope 5001 can be achieved. At this time, the arm control device 5045 can control driving of the arm 5031 by various known control methods such as force control or position control.

For example, by the surgeon 5067 performing an appropriate operation input via the inputting apparatus 5047 (including the foot switch 5057), driving of the arm 5031 may be appropriately controlled by the arm control device 5045 in accordance with the operation input, and the position and posture of the endoscope 5001 may be controlled. By this control, the endoscope 5001 at a distal end of the arm 5031 can be moved from any position to any position and then fixedly supported at the position after the movement. Note that the arm 5031 may be operated by what is called a master slave method. In this case, the arm 5031 can be remotely operated by the user via the inputting apparatus 5047 installed at a place away from the operating room.

Furthermore, in a case where the force control is applied, the arm control device 5045 may perform what is called power assist control to receive an external force from the user and drive the actuators of the respective joints 5033a to 5033c so that the arm 5031 moves smoothly according to the external force. Thus, when the user moves the arm 5031 while directly touching the arm 5031, the arm 5031 can be moved with a relatively light force. Therefore, the endoscope 5001 can be moved more intuitively and with a simpler operation, and convenience for the user can be improved.

Here, generally in endoscopic surgery, a doctor called a scopist supports the endoscope 5001. On the other hand, by using the support arm device 5027, it is possible to more reliably fix the position of the endoscope 5001 without manual labor. Thus, an image of the surgical site can be stably obtained, and it is possible to perform the operation smoothly.

Note that the arm control device 5045 does not necessarily have to be provided on the cart 5037. Furthermore, the arm control device 5045 does not necessarily have to be one device.

For example, the arm control device 5045 may be provided in each of the joints 5033a to 5033c of the arm 5031 of the support arm device 5027, and the plurality of arm control devices 5045 may cooperate with each other to implement driving control of the arm 5031.

### Light Source Apparatus

The light source apparatus 5043 supplies the endoscope 5001 with irradiation light for imaging a surgical site. The light source apparatus 5043 includes, for example, an LED, a laser light source, or a white light source including a combination thereof. At this time, in a case where a white light source is formed by a combination of RGB laser light sources, the output intensity and output timing of each color (each wavelength) can be controlled with high accuracy, and thus white balance of a captured image can be adjusted in the light source apparatus 5043. Further, in this case, if laser beams from the respective RGB laser light sources are irradiated time-divisionally on an observation target and driving of the imaging elements of the camera head 5005 are controlled in synchronism with the irradiation timings. Then images individually corresponding to the R, G and B colors can be also picked up time-divisionally. According to this method, a color image can be obtained even if color filters are not provided for the imaging element.

Furthermore, driving of the light source apparatus 5043 may be controlled so as to change the intensity of output light at every predetermined time interval. By controlling driving of the imaging element of the camera head 5005 in synchronism with the timing of the change of the intensity of light to acquire images time-divisionally and synthesizing the images, an image of a high dynamic range free from underexposed blocked up shadows and overexposed highlights can be created.

Furthermore, the light source apparatus 5043 may be capable of supplying light in a predetermined wavelength band corresponding to special light observation. In the special light observation, for example, what is called narrow band light observation (narrow band imaging) is performed by utilizing the wavelength dependence of light absorption in body tissue and emitting light in a narrower band as compared with irradiation light in normal observation (that is, white light), to thereby image a predetermined tissue such as blood vessels on a surface layer of a mucous membrane with high contrast. Alternatively, in special light observation, fluorescent observation for obtaining an image from fluorescent light generated by irradiation of excitation light may be performed. In the fluorescence observation, it is possible to perform irradiating a body tissue with excitation light to observe fluorescence from the body tissue (autofluorescence observation), or locally injecting a reagent such as indocyanine green (ICG) into a body tissue and irradiating the body tissue with excitation light corresponding to the fluorescence wavelength of the reagent to obtain a fluorescence image, or the like. The light source apparatus 5043 may be capable of supplying narrowband light and/or excitation light compatible with such special light observation.

### Camera Head and CCU

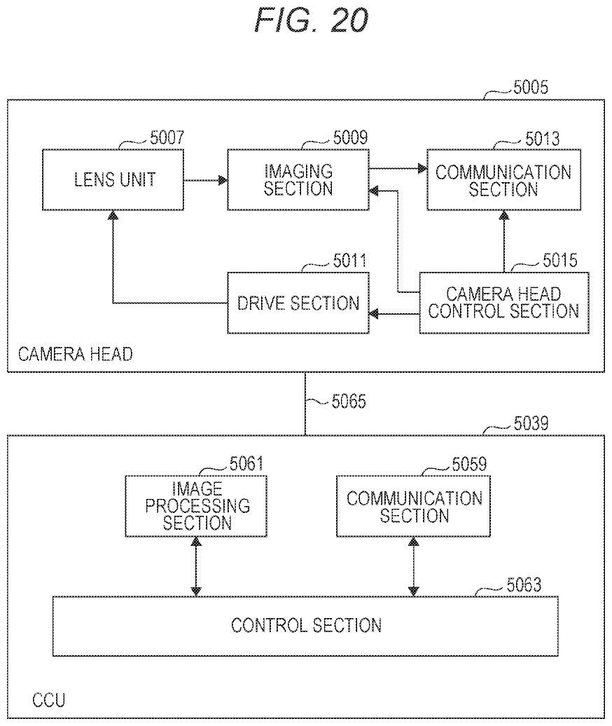

Functions of the camera head 5005 and the CCU 5039 of the endoscope 5001 will be described in more detail with reference to FIG. 20. FIG. 20 is a block diagram illustrating an example of a functional configuration of the camera head 5005 and the CCU 5039 illustrated in FIG. 19.

Referring to FIG. 20, the camera head 5005 has a lens unit 5007, an imaging section 5009, a drive section 5011, a communication section 5013, and a camera head control section 5015 as functions thereof. Furthermore, the CCU 5039 includes a communication section 5059, an image processing section 5061, and a control section 5063 as its functions. The camera head 5005 and the CCU 5039 are connected in a bidirectionally communicable manner by a transmission cable 5065.

First, a functional configuration of the camera head 5005 will be described. The lens unit 5007 is an optical system provided at a connection portion with the lens barrel 5003. The observation light taken in from the distal end of the lens barrel 5003 is guided to the camera head 5005 and incident on the lens unit 5007. The lens unit 5007 is configured by combining a plurality of lenses including a zoom lens and a focus lens. The lens unit 5007 has optical characteristics that are adjusted so that the observation light is condensed on a light receiving surface of the imaging element of the imaging section 5009. Furthermore, the zoom lens and the focus lens are configured so that their positions on the optical axis can be moved in order to adjust the magnification and focus of the captured image.

The imaging section 5009 includes an imaging element and is arranged at a subsequent stage of the lens unit 5007. The observation light that has passed through the lens unit 5007 is condensed on the light receiving surface of the imaging element, and an image signal corresponding to an observation image is generated by photoelectric conversion. The image signal generated by the imaging section 5009 is provided to the communication section 5013.

As the imaging element forming the imaging section 5009, for example, a complementary metal oxide semiconductor (CMOS) type image sensor, which has a Bayer array and is capable of color imaging, is used. Note that as the imaging element, for example, an imaging element capable of capturing a high-resolution image of 4K or higher may be used. By obtaining the image of a surgical site with high resolution, the surgeon 5067 can grasp the situation of the surgical site in more detail, and can proceed with the operation more smoothly.

Furthermore, the imaging element forming the imaging section 5009 includes a pair of imaging elements for acquiring respective image signals for the right eye and the left eye corresponding to 3D display. Performing the 3D display enables the surgeon 5067 to more accurately grasp the depth of living tissue at a surgical site. Note that in a case where the imaging section 5009 includes a multi-plate type, multiple systems of lens units 5007 are provided corresponding to the respective imaging elements.

Furthermore, the imaging section 5009 does not necessarily have to be provided in the camera head 5005. For example, the imaging section 5009 may be provided immediately behind the objective lens in the inside of the lens barrel 5003.

The drive section 5011 includes an actuator and moves the zoom lens and the focusing lens of the lens unit 5007 by a predetermined distance along an optical axis under the control of the camera head control section 5015. Consequently, the magnification and the focal point of a picked up image by the imaging section 5009 can be adjusted suitably.

The communication section 5013 includes a communication device for transmitting and receiving various kinds of information to and from the CCU 5039. The communication section 5013 transmits an image signal acquired from the imaging section 5009 as RAW data to the CCU 5039 through the transmission cable 5065. At this time, it is preferable that the image signal is transmitted by optical communication in order to display the captured image of the surgical site with low latency. At a time of surgery, the surgeon 5067 performs the surgery while observing the condition of the affected area with the captured image, and thus for safer and more reliable surgery, it is demanded to display the moving image of the surgical site in real time as much as possible. In a case where optical communication is performed, the communication section 5013 is provided with a photoelectric conversion module that converts an electric signal into an optical signal. The image signal is converted into an optical signal by the photoelectric conversion module and then transmitted to the CCU 5039 via the transmission cable 5065.

Furthermore, the communication section 5013 receives a control signal for controlling driving of the camera head 5005 from the CCU 5039. The control signal includes, for example, information regarding imaging conditions such as information specifying the frame rate of the captured image, information specifying the exposure value at the time of imaging, and/or information specifying the magnification and focus of the captured image. The communication section 5013 provides the received control signal to the camera head control section 5015. Note that the control signal from the CCU 5039 may also be transmitted by optical communication. In this case, the communication section 5013 is provided with a photoelectric conversion module that converts an optical signal into an electric signal, and the control signal is supplied to the camera head control section 5015 after being converted into an electric signal by the photoelectric conversion module.

Note that the imaging conditions such as the frame rate, exposure value, magnification, and focus described above are automatically set by the control section 5063 of the CCU 5039 on the basis of the acquired image signal. That is, the endoscope 5001 is equipped with what is called an auto exposure (AE) function, an auto focus (AF) function, and an auto white balance (AWB) function.

The camera head control section 5015 controls driving of the camera head 5005 on the basis of the control signal from the CCU 5039 received via the communication section 5013. For example, the camera head control section 5015 controls driving of the imaging element of the imaging section 5009 on the basis of the information specifying the frame rate of the captured image and/or the information specifying the exposure at the time of imaging. Furthermore, for example, the camera head control section 5015 appropriately moves the zoom lens and the focus lens of the lens unit 5007 via the drive section 5011 on the basis of the information specifying the magnification and focus of the captured image. The camera head control section 5015 may further include a function of storing information for identifying the lens barrel 5003 and the camera head 5005.

Note that by arranging components such as the lens unit 5007 and the imaging section 5009 in a highly airtight and waterproof sealed structure, the camera head 5005 can be made resistant to autoclave sterilization.

Next, a functional configuration of the CCU 5039 will be described. The communication section 5059 includes a communication device for transmitting and receiving various kinds of information to and from the camera head 5005. The communication section 5059 receives an image signal transmitted thereto from the camera head 5005 through the transmission cable 5065. At this time, as described above, the image signal can be preferably transmitted by optical communication. In this case, the communication section 5059 is provided with a photoelectric conversion module that converts an optical signal into an electrical signal, corresponding to the optical communication. The communication section 5059 provides the image signal converted into the electric signal to the image processing section 5061.

Further, the communication section 5059 transmits a control signal for controlling driving of the camera head 5005 to the camera head 5005. The control signal may also be transmitted by optical communication.

The image processing section 5061 performs various image processes for an image signal in the form of RAW data transmitted thereto from the camera head 5005. The image processing includes, for example, various known signal processing such as development processing, image quality enhancement processing (band enhancement processing, super-resolution processing, noise reduction (NR) processing, and/or camera shake correction processing, and the like), and/or enlargement processing (electronic zoom processing) and the like. Furthermore, the image processing section 5061 also performs detection processing on the image signal for performing AE, AF, and AWB.

The image processing section 5061 includes a processor such as a CPU or a GPU, and the processor operates according to a predetermined program, whereby the above-described image processing and detection processing can be performed. Note that, in a case where the image processing section 5061 includes a plurality of GPUs, the image processing section 5061 appropriately divides information related to an image signal, and performs image processing in parallel by the plurality of GPUs.

The control section 5063 performs various control related to imaging of a surgical site by the endoscope 5001 and display of a captured image thereof. For example, the control section 5063 creates a control signal for controlling driving of the camera head 5005. At this time, in a case where imaging conditions are input by the user, the control section 5063 generates a control signal on the basis of the input by the user. Alternatively, in a case where the endoscope 5001 is equipped with the AE function, the AF function, and the AWB function, the control section 5063 appropriately calculates an optimum exposure value, focal length, and white balance according to a result of detection processing by the image processing section 5061, so as to generate a control signal.

Furthermore, the control section 5063 causes the display device 5041 to display the image of the surgical site on the basis of the image signal subjected to the image processing by the image processing section 5061. At this time, the control section 5063 recognizes various objects in the surgical site image using various image recognition techniques. For example, the control section 5063 can detect the shapes of edges, colors, and the like of an object included in the surgical site image, to thereby recognize a surgical tool such as forceps, a specific biological part, bleeding, mist when using the energy treatment device 5021, or the like. When causing the display device 5041 to display the image of the surgical site, the control section 5063 uses a recognition result thereof to superimpose various surgical support information on the image of the surgical site. By the surgery support information superimposed and presented to the surgeon 5067, it is possible to proceed with the surgery more safely and reliably.

The transmission cable 5065 which connects the camera head 5005 and the CCU 5039 to each other is an electric signal cable ready for communication of an electric signal, an optical fiber ready for optical communication or a composite cable ready for both of electrical and optical communications.

Here, although the communication is performed by wire using the transmission cable 5065 in the illustrated example, the communication between the camera head 5005 and the CCU 5039 may be performed wirelessly. In a case where the communication between the two is performed wirelessly, it is not necessary to lay the transmission cable 5065 in the operating room, and thus situations in which the transmission cable 5065 hinders movement of the medical staff in the operating room can be eliminated.

The example of the endoscopic surgery system 5000 to which the technology according to the present disclosure can be applied has been described above. Note that, here, the endoscopic surgery system 5000 has been described as an example, but the system to which the technology according to the present disclosure can be applied is not limited to such an example. For example, the technology according to the present disclosure may be applied to a flexible endoscope system for examination or a microscopic surgery system.

The technology according to the present disclosure can be suitably applied to the imaging section 5009 among the configurations described above. Specifically, the semiconductor device 100 in FIG. 1 can be applied to the imaging section 5009. By applying the technology according to the present disclosure to the imaging section 5009, it is possible to improve the yield of the imaging section 5009.

Note that the embodiments described above illustrate an example for embodying the present technology, and matters in the embodiments and matters specifying the invention in the claims have respective correspondence relationships. Similarly, the matters specifying the invention in the claims and matters having the same names in the embodiments of the present technology have respective correspondence relationships. However, the present technology is not limited to the embodiments and can be embodied by making various modifications to the embodiments without departing from the gist thereof

Note that effects described in the present description are merely examples and are not limited, and other effects may be provided.

Note that the present technology can have configurations as follows.

(1) A semiconductor device, including:

a through electrode that penetrates a semiconductor substrate along a direction perpendicular to a predetermined front surface of the semiconductor substrate;

an insulating film covering the through electrode; and

a wiring layer that includes a dummy gate disposed in a region between an outer periphery of the insulating film and an inner periphery of the insulating film on the front surface.

(2) The semiconductor device according to (1) above, in which

the dummy gate is not disposed inside the inner periphery.

(3) The semiconductor device according to (1) or (2) above, in which

the dummy gate is further disposed outside the outer periphery.

(4) The semiconductor device according to (3) above, in which

the semiconductor substrate includes an element isolation region formed under the wiring layer, and

the dummy gate is disposed on an upper portion of the element isolation region.

(5) The semiconductor device according to any one of (1) to (4) above, in which

an area ratio of the dummy gate is not less than ten percent.

(6) The semiconductor device according to any one of (1) to (5) above, in which

a predetermined number of wirings are formed in the wiring layer, and

a pitch of the wirings inside the outer periphery is substantially equal to a pitch of the wirings outside the outer periphery.

(7) The semiconductor device according to any one of (1) to (6) above, in which

a gate electrode is further disposed in the wiring layer, and

a material of the dummy gate is same as a material of the gate electrode.

(8) The semiconductor device according to (7) above, in which

the material of the dummy gate is any of polycrystalline silicon, amorphous silicon, tungsten, titanium, tantalum, and aluminum.

(9) The semiconductor device according to (1) above, in which

a gate electrode is further disposed in the wiring layer, and

the material of the dummy gate is different from a material of the gate electrode.

(10) The semiconductor device according to (9) above, in which

a material of the dummy gate is silicon nitride.

(11) The semiconductor device according to any one of (1) to (10) above, in which

in the through electrode, a cross-sectional area of an upper end on a front surface side is smaller than a cross-sectional area of a lower end on a back surface side with respect to the front surface, and

the dummy gate is disposed between the outer periphery of the insulating film covering the upper end of the front surface and the inner periphery of the insulating film covering the upper end.

(12) The semiconductor device according to any one of (1) to (10) above, in which

in the through electrode, a cross-sectional area of an upper end on a front surface side is larger than a cross-sectional area of a lower end on a back surface side with respect to the front surface, and

the dummy gate is disposed between the outer periphery of the insulating film covering the lower end of the front surface and the inner periphery of the insulating film covering the lower end.

(13) The semiconductor device according to any one of (1) to (12) above, in which

the semiconductor substrate includes an element isolation region formed over an entire surface of a region between the outer periphery of the insulating film and the inner periphery of the insulating film.

(14) The semiconductor device according to any one of (1) to (12) above, in which

the semiconductor substrate includes an element isolation region formed in a part of a region between the outer periphery of the insulating film and the inner periphery of the insulating film, and

the dummy gate is disposed on an upper side of the element isolation region.

(15) The semiconductor device according to any one of (1) to (14) above, in which

a gate electrode of a Fin field-effect transistor (Fin-FET) is further disposed in the wiring layer.

(16) A method for manufacturing a semiconductor device, the method including:

a first dummy gate formation procedure of forming a first dummy gate in a predetermined region between two concentric circles having different areas on a predetermined front surface of a semiconductor substrate;

a polishing procedure of forming an interlayer insulating film on the front surface on which the first dummy gate is formed and polishing the interlayer insulating film;

a second dummy gate formation procedure of removing the first dummy gate and forming a second dummy gate with a material different from a material of the first dummy gate in the predetermined region; and

an insulating film formation procedure of forming, in the predetermined region, an insulating film for covering a through electrode penetrating the semiconductor substrate along a direction perpendicular to the front surface.

### REFERENCE SIGNS LIST

100 Semiconductor device
110 Semiconductor substrate
111 Element isolation region
120 Wiring layer
121 Diffusion preventing film
122 Wiring
123 Interlayer insulating film
124, 125 Gate electrode
126 Pad
130 Silicon dummy gate
131 Metal dummy gate
132 SiN dummy gate
140 Conductor
141 Through electrode
142 Conductive film
150 Insulator
151, 152 Insulating film
5009, 12031 Imaging section

What is claimed is:

1. A semiconductor device, comprising:
a through electrode that penetrates a semiconductor substrate along a direction perpendicular to a predetermined front surface of the semiconductor substrate;
an insulating film covering the through electrode; and
a wiring layer that includes a dummy gate disposed in a region between an outer periphery of the insulating film and an inner periphery of the insulating film on the front surface.

2. The semiconductor device according to claim 1, wherein
the dummy gate is not disposed inside the inner periphery.

3. The semiconductor device according to claim 1, wherein
the dummy gate is further disposed outside the outer periphery.

4. The semiconductor device according to claim 3, wherein
the semiconductor substrate includes an element isolation region formed under the wiring layer, and
the dummy gate is disposed on an upper portion of the element isolation region.

5. The semiconductor device according to claim 1, wherein
an area ratio of the dummy gate is not less than ten percent.

6. The semiconductor device according to claim 1, wherein
a predetermined number of wirings are formed in the wiring layer, and
a pitch of the wirings inside the outer periphery is substantially equal to a pitch of the wirings outside the outer periphery.

7. The semiconductor device according to claim 1, wherein
a gate electrode is further disposed in the wiring layer, and
a material of the dummy gate is same as a material of the gate electrode.

8. The semiconductor device according to claim 7, wherein
the material of the dummy gate is any of polycrystalline silicon, amorphous silicon, tungsten, titanium, tantalum, and aluminum.

9. The semiconductor device according to claim 1, wherein
a gate electrode is further disposed in the wiring layer, and
the material of the dummy gate is different from a material of the gate electrode.

10. The semiconductor device according to claim 9, wherein
a material of the dummy gate is silicon nitride.

11. The semiconductor device according to claim 1, wherein
in the through electrode, a cross-sectional area of an upper end on a front surface side is smaller than a cross-sectional area of a lower end on a back surface side with respect to the front surface, and
the dummy gate is disposed between the outer periphery of the insulating film covering the upper end of the front surface and the inner periphery of the insulating film covering the upper end.

12. The semiconductor device according to claim 1, wherein
in the through electrode, a cross-sectional area of an upper end on a front surface side is larger than a cross-sectional area of a lower end on a back surface side with respect to the front surface, and
the dummy gate is disposed between the outer periphery of the insulating film covering the lower end of the front surface and the inner periphery of the insulating film covering the lower end.

13. The semiconductor device according to claim 1, wherein
the semiconductor substrate includes an element isolation region formed over an entire surface of a region between the outer periphery of the insulating film and the inner periphery of the insulating film.

14. The semiconductor device according to claim 1, wherein
the semiconductor substrate includes an element isolation region formed in a part of a region between the outer periphery of the insulating film and the inner periphery of the insulating film, and
the dummy gate is disposed on an upper side of the element isolation region.

15. The semiconductor device according to claim 1, wherein
a gate electrode of a Fin field-effect transistor (Fin-FET) is further disposed in the wiring layer.

16. A method for manufacturing a semiconductor device comprising:
a first dummy gate formation procedure of forming a first dummy gate in a predetermined region between two concentric circles having different areas on a predetermined front surface of a semiconductor substrate;
a polishing procedure of forming an interlayer insulating film on the front surface on which the first dummy gate is formed and polishing the interlayer insulating film;
a second dummy gate formation procedure of removing the first dummy gate and forming a second dummy gate with a material different from a material of the first dummy gate in the predetermined region; and
an insulating film formation procedure of forming, in the predetermined region, an insulating film for covering a through electrode penetrating the semiconductor substrate along a direction perpendicular to the front surface.
